(19) United States
(12) Patent Application Publication
(10) Pub. No.: US 2023/0147544 A1
(43) Pub. Date: May 11, 2023

(54) Method of mounting suitable for positioning reeved components on a printed circuit board PCB

(71) Applicant: Fitech Sp. z o.o., Sucha Beskidzka (PL)

(72) Inventors: Pawel BOREK, Sucha Beskidzka (PL); Michal GRZADZIEL, Sucha Beskidzka (PL); Mariusz HUBCZAK, Slemien (PL); Piotr MISTRZYK, Konskie (PL); Pawel PALECZNY, Zembrzyce (PL); Lukasz POREBSKI, Sucha Beskidzka (PL); Dominik SZEWCZYK, Jelesnia (PL); Miroslaw TZRNADEL, Sucha Beskidzka (PL); Krzysztof PYCLIK, Zywiec (PL)

(73) Assignee: Fitech Sp. z o.o., Sucha Beskidzka (PL)

(21) Appl. No.: 17/980,857

(22) Filed: Nov. 4, 2022

(30) Foreign Application Priority Data
Nov. 6, 2021 (EP) 21461617.9

(51) Int. Cl. H05K 13/04

(52) U.S. Cl. CPC H05K 13/0406; H05K 13/0408

(57) ABSTRACT

A method of mounting components on a PCB includes drawing a component, transporting the component to a starting position, taring the sensor, moving the sensor in Z-axis until the component contacts the board surface, activating the regulator, transmitting from the regulator a signal to a industrial robot as Z-axis offset, releasing the components from the industrial robot if the Z-axis offset is greater than or equal to a preset parameter and establishing the current position of the component as a starting point, moving the component if the Z-axis offset is less than the preset parameter beginning from the current position, arresting movement of the component when the sensor detects an opening edge in the board, moving the component away from the opening edge based on data from the sensor, repeating steps while a change in the component movement is executed.

### FIELD

The aspects of the disclosed embodiments provide a method of mounting, suitable for positioning reeved components on a printed circuit board PCB, and in particular for embedding reeved electronics elements such as e.g. transistors, varistors, relays, capacitors on a board.

### BACKGROUND

In the prior art, methods for mounting elements are known which are carried out by robots with the use of computer software.

Document CN 108766894 A discloses a method for mounting a chip and a system for guiding of vision of a robot. A second industrial camera is additionally positioned within each PCB positioning area and within a chip positioning area; the robot is provided for absorbing chips that may be moved to stations of second industrial cameras; photographs of the absorbed chips are taken, and the angular difference between the included angle of the chip mounting surface and the horizontal axis so that the terminal actuator rotates in a P3 position within the angular difference, angular compensation is carried out, and the compensation is effected on X-axis and on Y-axis, a slip error is generated when chips are absorbed or in a transfer process upon enhanced chip absorption area and mounting accuracy enhancement, since a six-axes robot has a higher degree of freedom and elasticity, mounting of chips is effected within the workpieces such as cavities and flexible production is obtained; then on the robot arms the first industrial cameras are placed and the robot is easier to be moved and thus the position-based visual control method is more flexible and has a broader scope of application.

Document CN 109454638 A provides a robot grasping system based on visual guidance. The robot grasping system comprises a CCD camera, a lens, a light source, an industrial control computer and an industrial control robot, the CCD camera being an industrial camera and communicating with the computer via gigabit Ethernet; the CCD camera being installed over a belt conveyor flight. The lens is a fixed-focus lens. The source of light is an annular LED light source. Image information captured by the

CCD camera are received and converted into robot control signals to control the actual final robot position when recognition of the workpiece by means of an image processing algorithm is completed. The industrial control robot is provided with six rotational joints driven by an alternate current servomotor and is arranged for grasping operation in a production line. The robot grasping system has a higher accuracy and meets industrial-scale production requirements; the robot grasping system greatly contributing to enhancement of the automatization degree of the production line.

Document CN 103706568 A discloses a system and method for robotized sorting based on machine vision. The system comprises a CCD digital camera, a camera lens, a light source, a six-axes articulated robot main body, an electric control box and a vacuum cup. The CCD digital camera is connected to the industrial computer by means of a switch. The robot main body along with the six-axes articulated joint is connected to the electric control box. The electric control box has access to the switch. The vacuum cup is rigidly attached to the tail end of the six-axes robot main body along with the articulated joint. The camera is arranged to take photographs of the object being sorted, collecting data and transmitting data to an industrial computer by means of a switch. The industrial computer is provided for processing captured photographs of the object to be sorted, performing precise positioning and then outputting a control signal to the electric control box by means of the switch. The electric control box is arranged to control the six-axes articulation joint main body of the robot in order to carry out desired sorting processes according to the received control signal.

### SUMMARY

The aspects of the disclosed embodiments are directed to providing a method that enables automatization of time-consuming process of manual forming and mounting electronic reeved elements, by means of a robot arm with an algorithm that recognizes the place at which an element is positioned.

The method of mounting, suitable for positioning components on a PCB, with the use of an industrial robot comprising a force and/or a moment sensor as well as means for grasping and transporting a component, comprises the steps of:
a. drawing a component,
b. transporting the component to a predetermined starting position,
c. taring the force and/or moment sensor,
d. transporting the component in the Z-axis, meant as a height over the board surface, towards the board, until the component contacts the board surface,
e. actuating a regulator with determined parameters,
f. transferring to the regulator, when output data are stabilized, a signal from the means for grasping and transporting of the industrial robot as a Z-axis offset,
g. releasing the component from the means for grasping and transporting of the industrial robot if the Z-axis offset is greater than or equal to a preset parameter, and establishing the current position of the component as a starting point,
h. moving the component if the Z-axis offset is less than the preset parameter, starting from the current position point,
i. arresting movement of the component when the force and/or moment sensor detects an opening edge in the board,
j. moving the component away from the opening edge based on the data from the force and/or moment sensor,
k. repeating steps g.-j, while a change in the component movement is executed.

Preferably, step k is carried out if a predetermined maximum duration time or opening search area are not exceeded.

Preferably, before step a the following steps are performed:
m. transporting the component to a predetermined position with intentionally imposed X-axis and Y-axis offsets so as to prevent the component enter mounting openings,
n. taring the force and/or moment sensor,
o. tri-state Z-axis adjustment until Fz force is stabilized within a preset range,
p. recording the Z-axis starting position which position means detection of appropriate component height,
r. selecting regulator parameters,
s. actuating the regulator with determined parameters, the regulator output being transmitted as a Z-axis offset, while the X-axis and Y-axis offsets applied in the initial step being turned off,
t. recording the X-axis and Y-axis positions and the Z-axis offset, if the Z offset calculated by the regulator is greater than or equal to a preset percent value and passing to step a,
u. actuating opening search algorithm if the Z offset calculated by the regulator is less than the preset percent value,
   wherein the opening search algorithm comprises the steps of:
u1. moving the component if the Z-axis offset is less than a preset parameter, along a predetermined path, beginning from the current position point.
u2. arresting movement of the component, when the force and/or moment sensor detects an opening edge in the board,
u3. moving the component away from the opening edge based on the data from the force and/or moment sensor,
u4. changing the component movement direction and repeating steps u1-u4.

Preferably, step u4 is carried out if a predetermined maximum duration time or opening search area are not exceeded, steps m-u are repeated.

Preferably, the regulator parameters are the proportional, integrating and differentiating parts set-ups.

Preferably, selection of the regulator parameters in step r is performed by Ziegler/Nichols oscillation method.

Preferably, the predetermined path along which the component is moving, has a spiral shape, preferably a square spiral shape.

Preferably, the depth at which the component is embedded in the board is calculated based on the rigidity of the board and the element insertion length.

Preferably, the component is positioned in a greater number of openings.

Preferably, the moment at which an opening edge is detected occurs as appearance of a force resultant from Fx and Fy forces above a preset maximum horizontal force.

Preferably, at the moment at which an opening edge is detected, the component is moved away according to the direction of a force resultant from Fx and Fy forces, to bring the value of the force resultant from Fx and Fy forces to a value below a preset value of a minimum horizontal force.

A computer program comprising instructions that cause, when the program is executed by the computer, that the computer executes the method according to the aspects of the disclosed embodiments.

A computer-readable memory comprising instructions that cause, when the program is executed by the computer, that the computer executes the method according to the invention.

### ADVANTAGEOUS EFFECTS OF THE DISCLOSURE

The use of the method according to the present disclosure accelerates the process of mounting reeved electronic elements on PCBs. It will be also possible to automatize the process by changing the manual forming and mounting operations into an automated process with the use of a robotic arm. Moreover, forming is effected in a machine when feeding elements, and not in a separate process, and this also facilitates and speeds-up the process. Additionally, it is possible to use the subject method for mounting elements in short batch production.

### DETAILED DESCRIPTION OF AN ADVANTAGEOUS EMBODIMENT OF THE DISCLOSURE

A method of mounting, preferably reeved electronic elements, on a PCB, according to the first preferable embodiment of the present disclosure, is carried out with the use of an industrial robot. Industrial robot is preferably provided with a robotic arm with a force and/or moment sensor attached thereto, and a tool changer to which a gripper with fingers is attached. In an embodiment, rod feeders, radial feeders or tray feeders are used, but a person skilled in the art will be aware that any mechanical solution may be used that enables raising and mounting elements.

In a preferable embodiment the force and/or moment sensor is of a six-axes type and to the control system feedback is provided in a form of forces that are applied to the element being mounted in any of the six axes. The use of the force and/or moment sensor makes it possible to simulate the sense of touch used by a human being (operator) when mounting the same elements manually.

Gripper and movable fingers are intended for gripping an element to be embedded. According to the shape, the gripper fingers adjust to the thickness of the component and thereby ensure proper clamping thereof to prevent slipping of the element from the robot gripper.

Data loading and operation of the machine is carried out with the use of an HMI (Human-Machine Interface) operator panel, provided with a PLC controller positioned on the machine panel. It makes it possible for the user to visualize and preform the following operations:

basing of the machine
loading, change or interruption of mounting command,
preview of the status of the accessories the machine is provided with,
preview of the service menu (e.g., manual control, preview of signals)
preview and cancelling alarms,
preview of the screen with basic data on the mounting in progress,
preview of the screen with basic statistics of the machine.
user authentication at two levels according to the capabilities conferred to him/her,
easy change of the language (PL, EN) for the entire visualization.

Process program generator is easy and intuitive and does not require specialist programming knowledge. For generating mounting sequences Pick&place data are used that are commonly used also in other machines. This enables the operator quick introduction or editing of mounting sequences for new or already existing products. For example, addition of four additional elements into a mounting sequence is possible within less than 10 minutes. The software is based on a cloud-operating application.

Monitoring software further enables both preview (in time) of such parameters as: mounting effectiveness, machine use rate, partial mounting duration time, PCBs flow duration time, number of mounted PCBs, number of mounted components, currently processed command, machine status, alarms set on the device, machine configuration.

The first step in the component mounting process comprises generating a mounting recipe with the use of the mentioned application. Programming is fast and easy, it enables building of a program for mounting over a dozen of elements within less than 30 minutes. Then a next product enters the machine. Loading of a mounting recipe for a specific product is carried out.

A further step is performing of calibration process. Calibration functions are aimed at levelling the impact of the rigidity degree of the PCB at a given point where the selected THT component is to be embedded. This process is recalled once for each new component to be mounted on a given PCB on a given machine.

In performing calibration process the robot arm draws a component and transports it to a predetermined position with intentionally imposed X-axis and Y-axis offsets to prevent the component from entering mounting openings. When the robot arm reaches the predetermined position, taring of the force and/or moment sensor is carried out and tri-state Z-axis adjustment is performed until Fz force becomes stabilized within a preset range, which is interpreted by the algorithm as component introductory portion abutting the surface of PCB. Then the Z-axis starting position is recorded which position means detection of the appropriate component height. A further process step comprises selecting parameters of the regulator the latter being afterwards actuated with the determined parameters, the regulator output being transmitted as a Z-axis offset, while the X-axis and Y-axis offsets applied in the initial step being turned off. The positions of the X-axis and Y-axis are recorded for the Z-axis offset, if the Z offset calculated by the regulator is greater than or equal to a preset percent value, and passing to step of mounting the element on the PCB is initiated. If the Z offset calculated by the regulator is less than a preset percentage (depending on the rigidity of the PCB) of the length of the component leg (situation interpreted by the algorithm as the component abutting the surface of the PCB), the opening search algorithm is actuated (regulator, preferably a PLC controller, transfers the X and Y axes offsets to the robot to make the robot drive following a square spiral when searching for openings). At the moment when excessive values for the forces Fx and Fy (interpreted as the component legs abutting the opening edge) are stated interruption

of the robot program is activated (the robot arrests its motion), an X-axis and Y-axis compensation mechanism is activated (retracting the robot at a predetermined position to make the forces drop below limits), and the spiral movement direction is changed. Additionally, the robot corrects the Z-axis twist (if the Z-axis force moment exceeds preset limits).

It should be noted that throughout the specification designations X, Y and Z for the forces and axes are defined relative to the board on which an element is being mounted. Z direction is a direction perpendicular to the board and X and Y directions are directions which are perpendicular to each other and parallel to the board.

In a preferable embodiment, selection of the regulator parameters is performed by Ziegler/Nichols oscillation method, and the regulator parameters are proportional, integrating and differentiating portion setups.

In an embodiment, opening search process consists on moving of the component if the Z-axis offset is less than a preset parameter, along a predetermined path, preferably in a shape of a square spiral, beginning from the current position point. When the force and/or moment sensor detects an opening edge in the board, the movement of the component is arrested. The component is moved away from the opening edge based on the data from the force and/or moment sensor. If a preset maximum duration time or opening search area have not been exceeded, the component movement direction is changed and the opening search procedure is repeated. If the maximum duration time or the opening search area is exceeded, the procedure is terminated with a negative effect and it needs to be repeated.

The moment when an opening edge is detected occurs as appearance of a value of the force resultant from Fx and Fy forces above a maximum horizontal force. Additionally, at the moment when an opening edge is detected the component is moved away according to the direction of the force resultant from Fx and Fy forces to bring the value of the force resultant from Fx and Fy forces to a value below a preset minimal horizontal force value.

Upon calibration of the device for mounting a given component on a specific board, elements are mounted on the board. Element is drawn by the gripper fingers of the robot arm, and next the component is transported to a predetermined starting

position. When it reaches the predetermined starting position, the force and/or moment sensor is subject to taring. When the sensor is tared, the component is moved in the direction of the Z-axis, i.e. its height over the surface of the board is decreased, until the component contacts the board surface. At the moment when the board is contacted by the component, the regulator with determined parameters is activated, and the preset pressing force of the component is constant and it is about 30% of the preset value. This value is an experimental value and a person skilled in the art will be aware how, based on routine measurements, this value should be established. A further step comprises transmitting from the regulator, when the output data are stabilized, of a signal to means for gripping and transporting the industrial robot as a Z-axis offset. The component is released from the means for gripping and transporting the industrial robot, if the Z-axis offset is greater than or equal to a preset parameter and the current position of the component is established as the starting point. On the other hand, if the Z-axis offset is less than the preset parameter, then the component is moved along a part in a shape of a spiral, preferably a square spiral, beginning from the current position point. When the force and/or moment sensor detects an opening edge, then the movement of the component is arrested. The component is moved away from the opening edge based on the data from the force and/or moment sensor. Then the process of moving the component along the path in the shape of a spiral is assumed again if the maximum duration time or opening search area are not exceeded, and then a change in the movement direction is made.

When the element becomes embedded, a further element is taken and the whole process is repeated. The step of embedding further elements is repeated until all the components according to the recipe are mounted.

The depth at which a component is embedded within the board is calculated based on the rigidity of the board and the element insertion length, the component being positioned in one or more openings.

A method of mounting according to a further preferable embodiment enables embedding elements that require preforming, since preforming is executed on a machine during feeding elements, and not in a separate process.

Moreover, in the case of a change of the element to be embedded, resetting of the machine takes less than 1 minute and no change in feeders is necessary.

According to another preferable embodiment, the components are terminated in metallic legs. When mounting, the legs are inserted into openings.

1. A method for mounting, suitable for positioning reeved component on a PCB, by means of an industrial robot that comprises a force and/or moment sensor and means for gripping and transporting a component, comprising the steps of:
a. drawing a component,
b. transporting the component to a predetermined starting position,
c. taring the force and/or moment sensor,
d. transporting the component in the Z-axis, defined as a height over the surface of the board, in the direction of the board, until the component contacts the board surface,
e. actuating a regulator with determined parameters,
f. transmitting from the regulator, when output data are stabilized, of a signal to means for gripping and transporting of the industrial robot as Z-axis offset,
g. releasing the component from the means for gripping and transporting of the industrial robot, if the Z-axis offset is greater than or equal to a preset parameter, and establishing the current position of the component as a starting point,
h. moving the component, if the Z-axis offset is less than a preset parameter, along a predetermined path, beginning from the current position point,
i. arresting the movement of the component, when the force sensor and/or the moment sensor detect an opening edge in the board,
j. moving the component away from the opening edge based on data from the force and/or moment sensor,
k. repeating steps g.-j, while a change in the component movement is executed.

2. The method according to claim 1, wherein step k is carried out if a predetermined maximum duration time or opening search area are not exceeded.

3. The method according to claim 1, wherein before step a the following steps are carried out:
m. transporting the component to a predetermined position with intentionally imposed X-axis and Y-axis offsets so as to prevent the component enter mounting openings,
n. taring the force and/or moment sensor,
o. tri-state Z-axis adjustment until Fz force is stabilized within a preset range,
p. recording the Z-axis starting position which position means detection of appropriate component height,
r. selecting regulator parameters,
s. activating the regulator with determined parameters, the regulator output being transmitted as a Z-axis offset, and the X-axis and Y-axis offsets applied in the initial step being turned off,
t. recording X-axis and Y-axis positions and Z-axis offset, if the Z offset calculated by the regulator is greater or equal to a preset percent value, and passing to step a,
u. activating opening search algorithm if the Z offset calculated by the regulator is less than the present percent value, wherein the opening search algorithm comprises the steps of:
u1. moving the component, if the Z-axis offset is less than a preset parameter, along a predetermined path, beginning form the current position point.
u2. arresting the movement of the component, when the force sensor and/or the moment sensor detect an opening edge in the board,
u3. moving the component away from the opening edge based on data from the force and/or moment sensor,
u4. changing the component movement direction and repeating steps u1-u4.

4. The method according to claim 1, wherein step u4 is carried out if a predetermined maximum duration time or opening search area are not exceeded, steps m-u are repeated.

5. The method according to claim 1, wherein the regulator parameters are proportional, integrating and differentiating portions setups.

6. The method according to claim 1, wherein selecting of the regulator parameters in step r is performed by Ziegler/Nichols oscillation method.

7. The method according to claim 1, wherein the predetermined path along which the component is moving has a shape of a spiral, preferably a square spiral.

8. The method according to claim 1, wherein the depth at which the component is embedded within the board is calculated based on the rigidity of the board and the element insertion length.

9. The method according to claim 1, wherein the component is placed in a greater number of openings.

10. The method according to claim 1, wherein the moment when an opening edge is detected occurs as appearance of a value of the force resultant from Fx and Fy forces above a preset maximum horizontal force.

11. The method according to claim 10, wherein at the moment when an opening edge is detected the component is moved away according to the direction of the force resultant from Fx and Fy forces to bring the value of the force resultant from Fx and Fy forces to a value between a preset minimum horizontal force value.

12. Computer program comprising instructions which cause, when the program is executed by a computer, the computer carry out the method according to claim 1.

13. Computer-readable memory comprising instructions which cause, when the program is executed by a computer, the computer carry out the method according to claim 1.
